(19) United States
(12) Patent Application Publication
(10) Pub. No.: US 2008/0239650 A1
(43) Pub. Date: Oct. 2, 2008

(54) MOUNTING ELECTRONIC COMPONENTS

(75) Inventors: Yoshirio Fujie, Kanagawa-ken (JP); Kenji Hidaka, Kanagawa-ken (JP); Koji Nakase, Kamakura (JP); Michihiro Okamoto, Kanagawa-ken (JP); Kenneth Robert Schneebeli, San Jose, CA (US); Takeshi Wagatsuma, Kanagawa (JP)

Correspondence Address: KONRAD RAYNES & VICTOR, LLP.;ATTN: IBM37, 315 SOUTH BEVERLY DRIVE, SUITE 210, BEVERLY HILLS, CA, 90212, US

(73) Assignee: INTERNATIONAL BUSINESS MACHINES CORPORATION, Armonk, NY (US)

(21) Appl. No.: 11/692,555

(22) Filed: Mar. 28, 2007

(51) Int. Cl. G06F 1/16; H05K 7/12

(52) U.S. Cl. 361/685

(57) ABSTRACT

Provided is an apparatus comprising a tray coupled to leaf spring mounts with multiple guide slots, the multiple guide slots adapted to receive multiple guide pins coupled to an electronic component, the leaf spring mounts adapted to hold the electronic component in a pre-determined position with spring force.

### CROSS-REFERENCE TO RELATED APPLICATIONS

This application is related to commonly owned and co-pending Application No. entitled “TOOL-LESS ELECTRONIC COMPONENT RETENTION,” by Michael Allen Curnalia, et al., Docket No. SJO920060069US1, filed on ______, and which is incorporated by reference herein in its entirety.

### BACKGROUND

1. Field

Embodiments of the invention relate to mounting electronic components.

2. Description of the Related Art

Some electronic components have a first connector that is capable of connection to a second connector of a system unit or device. For example, a Hard Disk Drive (HDD) has a first connector that is capable of connecting to a second connector coupled to a Printed Circuit Board (PCB). When these electronic components that have connectors are mounted into system units or devices, it is common to slide the electronic components into their mating connector from the opposite side and fix the electronic components using fastening parts, such as screws or more complicated apparatuses.

For accurate connector mating, electronic component positioning is important and needs to be defined exactly in X, Y, and Z directions. Conventional design techniques (such as fastening screws and mounting holes) require detailed design of each positioning component (i.e., parts to mount the electronic component in a desired position) and may result in parts' quantities/variety and system unit or device complication. In such cases, a large space is needed for mounting electronic components within system units or devices.

If screws or special fasteners are used for mounting electronic components, tools (such as a screw driver) are required on hand for removal and fastening. Moreover, if changing the direction or posture of system units or devices is required, workability becomes very bad. That is, changing the direction or posture causes additional procedures, and assembly or disassembly operation may become complicated.

Thus, there is a need in the art for improved mounting of electronic components.

### SUMMARY OF EMBODIMENTS OF THE INVENTION

Provided is an apparatus comprising a tray coupled to leaf spring mounts with multiple guide slots, the multiple guide slots adapted to receive multiple guide pins coupled to an electronic component, the leaf spring mounts adapted to hold the electronic component in a pre-determined position with spring force.

### BRIEF DESCRIPTION OF THE DRAWINGS

Referring now to the drawings in which like reference numbers represent corresponding parts throughout:

FIG. 1A illustrates a bottom view of a hard disk drive mounting configuration in accordance with certain embodiments.

FIG. 1B illustrates a top view of a hard disk drive mounting configuration in accordance with certain embodiments.

FIG. 2A illustrates a top view of a hard disk drive mounting structure with guide pins in accordance with certain embodiments.

FIG. 2B illustrates a bottom view of a hard disk drive mounting structure with guide pins in accordance with certain embodiments.

FIGS. 3A and 3B illustrate hard disk drive installation in accordance with certain embodiments.

FIG. 4 illustrates a top view of a hard disk drive that has been mounted into a tray in accordance with certain embodiments.

FIGS. 5A, 5B, and 5C illustrate a hard disk drive mounting procedure in accordance with certain embodiments.

FIG. 6 illustrates a cross section of a guide pin in accordance with certain embodiments.

FIG. 7A illustrates a cross-section of a center portion of a hard disk drive in accordance with certain embodiments.

FIG. 7B illustrates a cross-section of a side portion of a hard disk drive in accordance with certain embodiments.

### DETAILED DESCRIPTION

In the following description, reference is made to the accompanying drawings which form a part hereof and which illustrate several embodiments of the invention. It is understood that other embodiments may be utilized and structural and operational changes may be made without departing from the scope of the invention.

Embodiments provide a new mechanism that enables easy installation and sure connection of electronic components into system units or devices, without using tools. Such electronic components (e.g., hard disk drives) have connectors. With embodiments, these electronic components may be positioned quickly and precisely and mounted firmly within system units or devices using leaf spring mounts with a guiding function incorporated. Furthermore, since electronic components can be removed and replaced easily with embodiments, maintenance workability is improved. With embodiments, a tray incorporates and carries one or more hard disk drives on a Printed Circuit Board (PCB).

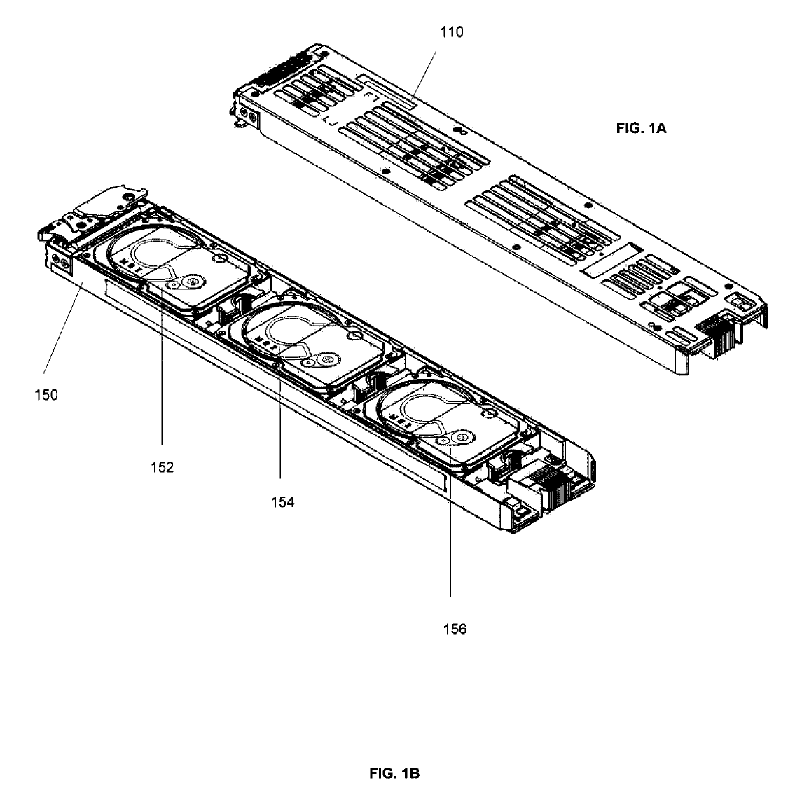

FIG. 1A illustrates a bottom view 110 of a hard disk drive mounting configuration in accordance with certain embodiments. FIG. 1B illustrates a top view 150 of a hard disk drive mounting configuration in accordance with certain embodiments. In this illustration, the bottom view 110 and top view 150 each include three hard disk drives (i.e., hard disk drives 152, 154, 156, which can be seen in the top view 150). For example, if the top view 150 were flipped over, the bottom view 110 would be seen.

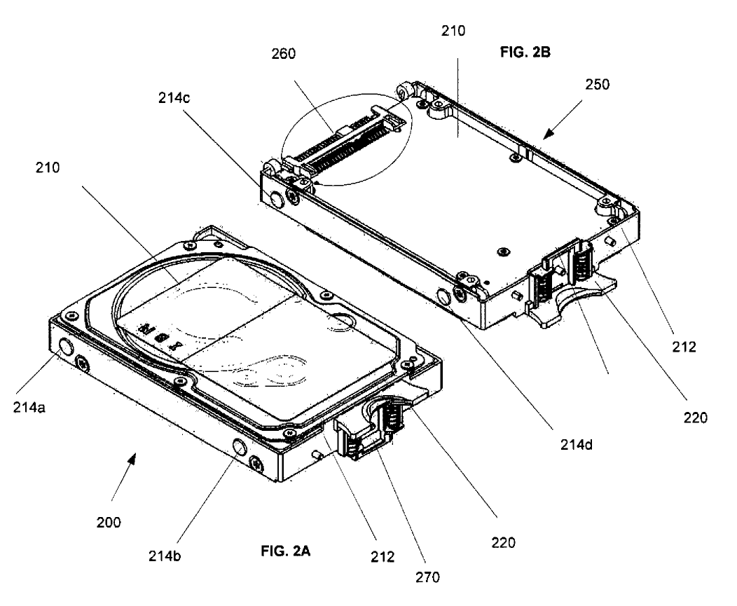

FIG. 2A illustrates a top view 200 of a hard disk drive mounting structure with guide pins in accordance with certain embodiments. FIG. 2B illustrates a bottom view 250 of a hard disk drive mounting structure with guide pins in accordance with certain embodiments. The hard disk drive illustrated in FIGS. 2A and 2B may be one of the hard disk drives 152, 154, 156 (FIG. 1). The hard disk drive 210 is structurally held by a metal support 212, two guide pins 214a and 214b (shown in FIG. 2A) are respectively staked in the right and left sides of one side of the metal support 212, and two guide pins 214c, 214d (shown in FIG. 2B) are respectively staked in the right and left sides of another side of the metal support 212. The hard disk drive 210 has a connector 260 for connection to a PCB. In addition, a latch mechanism 220 is coupled to the metal support 212. The latch mechanism 220 includes a latch tongue (i.e., the portion of the latch mechanism 220 that is inserted into a retention hole on the PCB).

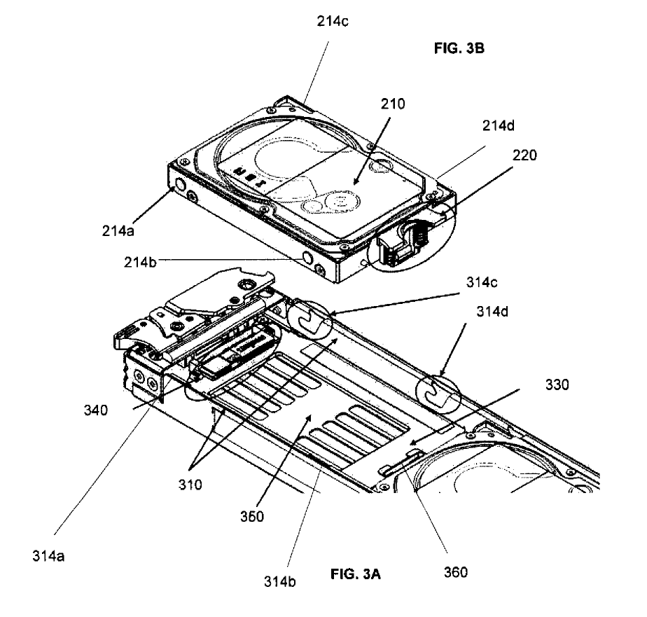

FIGS. 3A and 3B illustrate hard disk drive 210 installation in accordance with certain embodiments. PCB 330 is placed into tray 350, and leaf spring mounts 310 are coupled to the sides of the tray 350 at predetermined positions. The tray 350 may also be referred to as a housing. Each leaf spring mount 310 may be described as a flexible elastic object used to store mechanical energy and that is reverse U-shaped and produces a spring force. A connector 340 is mounted on the PCB 330, and the hard disk drive 210 is slid towards connector 340 so that connector 340 is coupled to (i.e., mated with) connector 260 on the hard disk drive 210. One leaf spring mount 310 includes guide slots 314a, 314b, and the other leaf spring mount includes guide slots 314c, 314d, where the guide slots 314a, 314b, 314c, 314d include holes for guiding and holding guide pins 214a, 214b, 214c, 214d, respectively. The PCB 330 includes a retention hole 360 into which the latch tongue of the latch mechanism 220 is inserted.

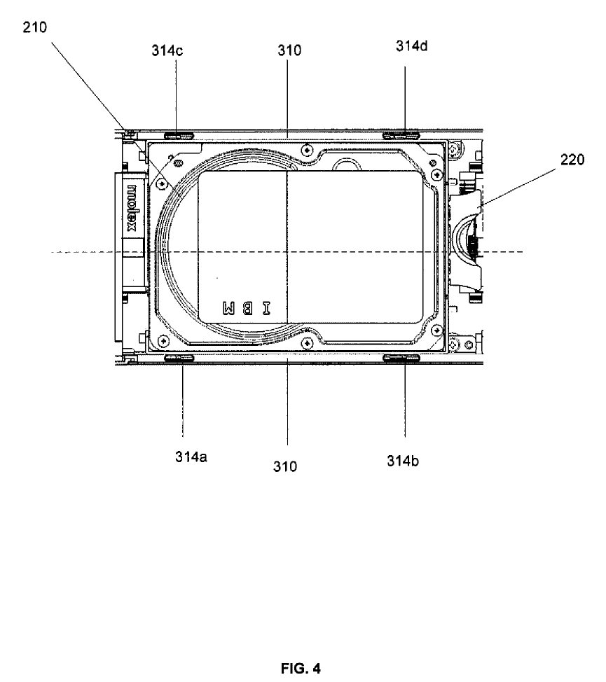

FIG. 4 illustrates a top view of a hard disk drive 210 that has been mounted into a tray 350 in accordance with certain embodiments. Guide slots 314a, 314b, 314c, 314d are illustrated in leaf spring mounts 31 0. The hard disk drive 210 with prepared guide pins 214a, 214b, 214c, 214d is inserted toward PCB 350 according to guide slots 314a, 314b, 314c, 314d on the leaf spring mounts 310. Additionally, connector 260 is coupled to connector 340 as part of the procedure of inclusion of the hard disk drive 210 in the tray 350.

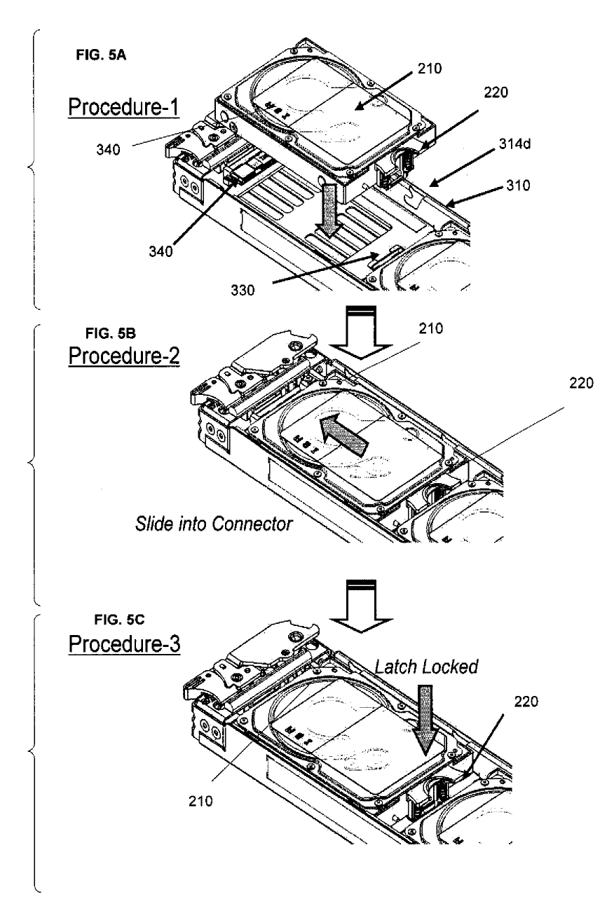

FIGS. 5A, 5B, and 5C illustrate a hard disk drive mounting procedure in accordance with certain embodiments. In FIG. 5A, the hard disk drive 210 is being inserted into the tray 350, and in FIG. 5B, the hard disk drive 210 has been inserted into the tray 350. Since latch mechanism 220 is coupled to the hard disk drive 210, the latch tongue locks the position when the hard disk drive 210 moves in place and its connector is mated with the other connector 340 on the PCB 330 (FIG. 5C). When the latch is locked, the latch is inserted into the retention hole. Moreover, the leaf spring mounts 310 stick to the hard disk drive 210, which is firmly held by the restitution of the leaf spring mounts 310 that surround the hard disk drive 210 on both sides. Furthermore, the positioning causes the electronic products (e.g., the HDD) to arrange in the center automatically by the restitution of the leaf spring mounts 310. That is, when the HDD 210 is mounted in place, the HDD 210 is automatically aligned in a center position, ready for exact mating with the connector 340 on the PCB 330 by the spring force from each of the leaf spring mounts 310. In this manner, embodiments provide a self centering function (e.g., see the dashed line of FIG. 4).

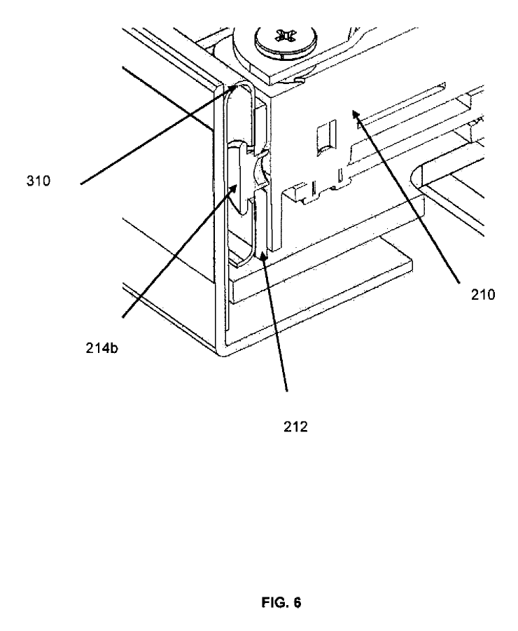

FIG. 6 illustrates a cross section of a guide pin in accordance with certain embodiments. The guide slot 314b has a larger opening and a narrower slot end, and the guide pin 214b has a larger head that enters the guide slot 314b and moves to the narrow end of the guide slot 314b. Since the head of the guide pin 214b is large, the guide pin 214b does not come out from the guide slot 314b.

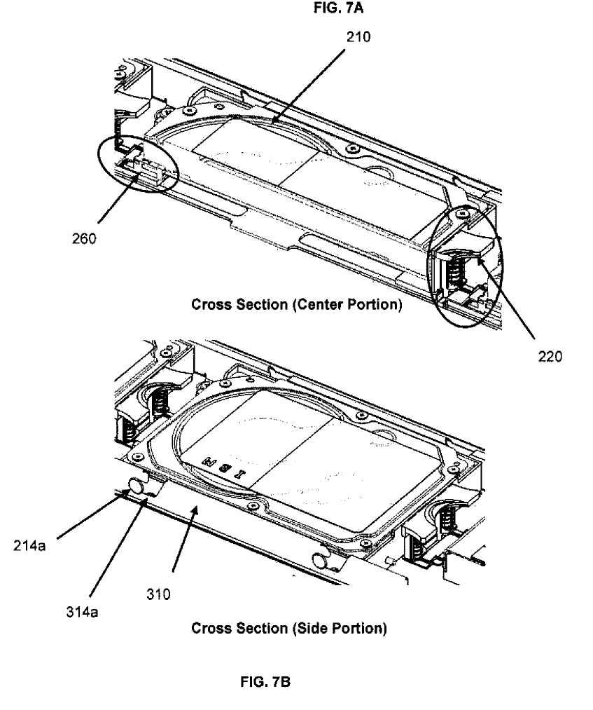

FIG. 7A illustrates a cross-section of a center portion of a hard disk drive in accordance with certain embodiments. FIG. 7B illustrates a cross-section of a side portion of a hard disk drive in accordance with certain embodiments. In FIG. 7A, as for the connector 260, the amount of required movements is decided by terminal form. According to this amount of movement, the form of the guide slots 314a, 314b, 314c, 314d is designed so that each guide slot 314a, 314b, 314c, 314d may be made to interlock with a respective guide pin 214a, 214b, 214c, 214d. Thereby, each guide pin 214a, 214b, 214c, 214d prepared in hard disk drive 210 moves along with guide slot 314a, 314b, 314c, 314d and is capable of performing connector 260, 340 connection certainly. That is, the connector 260 has the required slide moving distance to be fully mated, and the shape of the guide slots 314a, 314b, 314c, 314d is designed so that the guide pins 214a, 214b, 214c, 214d can move along with the guide slots 314a, 314b, 314c, 314d until the connection is completed on the PCB 330. In this case, connection is possible, without adding stress to connector 260 in the upper-and-lower-sides and right-and-left direction. That is, the HDD 210 is self-aligned by the interlocking between the guide slots 314a, 314b, 314c, 314d and the guide pins 314a, 314b, 314c, 314d, and the connection is smoothly and exactly completed.

As illustrated in FIGS. 7A and 7B, embodiments prevent the electronic products (e.g., hard disk drives) from completely separating from apparatus and equipment (e.g., the tray 350) by preparing the latch mechanism 220 to the opposite side of the connector 260.

In the attachment and detachment of electronic components that have connectors (e.g., hard disk drives), embodiments provide an easily incorporable mechanism for a predetermined position, without use of a tool. Moreover, the function of positioning and maintenance of parts uses limited space in the system unit or device. From a viewpoint of workability, the mechanism is able to respond to the exchange in maintenance of the electronic products incorporated at once (i.e., enables easy and simple operation during maintenance procedures).

Thus, embodiments provide leaf spring mounts with a guiding function incorporated. Then, a hard disk drive or other electronic component with a connector may be efficiently, easily, and certainly positioned such that the connector is coupled to a second connector. Such a mechanism also enables the electronic component to be easily removed for maintenance or other reasons, without use of a tool (such as a screw driver).

In addition, moving distance and direction of the parts with which the electronic component is equipped are controlled by the shape of the guide slot. Moreover, by applying the spring force of the leaf spring mount, the electronic component is held certainly and anti-vibration/shock nature is improved as the leaf spring mounts absorb vibrations and shocks. In addition, the leaf spring mounts provide a thermal transfer mechanism that enables the electronic component to remain cool.

The foregoing description of embodiments of the invention has been presented for the purposes of illustration and description. It is not intended to be exhaustive or to limit the embodiments to the precise form disclosed. Many modifications and variations are possible in light of the above teaching. It is intended that the scope of the embodiments be limited not by this detailed description, but rather by the claims appended hereto. The above specification, examples and data provide a complete description of the manufacture and use of the composition of the embodiments. Since many embodiments may be made without departing from the spirit and scope of the embodiments, the embodiments reside in the claims hereinafter appended or any subsequently-filed claims, and their equivalents.

What is claimed is:

1. An apparatus, comprising:
a tray coupled to leaf spring mounts with multiple guide slots, the multiple guide slots adapted to receive multiple guide pins coupled to an electronic component, the leaf spring mounts adapted to hold the electronic component in a pre-determined position with spring force.

2. The apparatus of claim 1, wherein the electronic component comprises a metal support to which the multiple guide pins are coupled, a first connector capable of mating with a second connector on a printed circuit board, and a latch mechanism.

3. The apparatus of claim 1, wherein the leaf spring mounts absorb vibrations.

4. The apparatus of claim 1, wherein the leaf spring mounts act as a thermal transfer mechanism to transfer heat from the electronic component.

5. The apparatus of claim 1, wherein the leaf spring mounts with the multiple guide slots enable a self centering function for the electronic component.

6. The method of claim 1, wherein each of the leaf spring mounts comprises a flexible elastic object used to store mechanical energy and that is reverse U-shaped and produces the spring force.

7. The apparatus of claim 1, wherein each of the multiple guide slots includes a larger opening for easy lead-in and a narrower slot end for moving the electronic component in place toward the second connector, and wherein the multiple guide slots guide positioning of the electronic component.

8. The apparatus of claim 6, wherein each of the multiple guide pins has a larger head that is inserted into the larger opening of a respective one of the multiple guide slots and that is moved towards the narrower slot end, such that each of the multiple guide pins does not come out from each of the multiple guide slots.

9. The apparatus of claim 1, wherein the electronic component comprises a hard disk drive.

10. An apparatus, comprising:
a hard disk drive coupled to multiple guide pins; and
leaf spring mounts with multiple guide slots, the multiple guide slots adapted to receive the multiple guide pins coupled to the hard disk drive, wherein the leaf spring mounts are adapted to hold the hard disk drive in a pre-determined position with spring force.

11. The apparatus of claim 10, wherein the hard disk drive comprises a first connector capable of mating with a second connector on a printed circuit board.

12. The apparatus of claim 10, wherein the hard disk drive is coupled to a metal support, and wherein the multiple guide pins are staked in right and left sides of the metal support.

13. The apparatus of claim 10, wherein the hard disk drive with the multiple guide pins is adapted to being inserted toward a printed circuit board according to the multiple guide slots on the leaf spring mounts.

14. The apparatus of claim 10, wherein each of the multiple guide slots includes a larger opening for easy lead-in and a narrower slot end for moving the electronic component in place toward the second connector, and wherein the multiple guide slots guide positioning of the electronic component.

15. The apparatus of claim 10, wherein each of the multiple guide pins has a larger head that is inserted into the larger opening of a respective one of the multiple guide slots and that is moved towards the narrower slot end, such that each of the multiple guide pins does not come out from each of the multiple guide slots.
